(19) United States
(12) Patent Application Publication
(10) Pub. No.: US 2026/0238179 A1
(43) Pub. Date: Aug. 13, 2026

(54) SLANTED RESONATOR

(71) Applicant: KYOCERA Technologies Oy, Espoo (FI)

(72) Inventors: Hannu VESTERINEN, Espoo (FI); Jan KUYPERS, Espoo (FI)

(21) Appl. No.: 19/471,709

(22) PCT Filed: Mar. 27, 2024
(86) PCT No.: PCT/FI2024/050152

§ 371 Date: Oct. 2, 2025

(30) Foreign Application Priority Data
Apr. 19, 2023 (FI) 20235440

(51) Int. Cl. H03H 9/02; H03H 9/13; H03H 9/15; H03H 9/17; H03H 9/205

(52) U.S. Cl. CPC H03H 9/02244; H03H 9/13; H03H 9/17; H03H 9/205; H03H 2009/02322; H03H 2009/155

(57) ABSTRACT

A MEMS, microelectromechanical systems, resonator (10) comprising a slanted resonator element, the slanted resonator element comprising a slanted resonating beam (11) comprising single-crystalline silicon, wherein the slanted resonating beam (11) is configured to resonate in its length direction, and wherein a longitudinal axis (150) of the slanted resonating beam (11) is slanted from a <100>direction of silicon.

### FIELD

The present disclosure generally relates to microelectromechanical systems, MEMS, resonators.

### BACKGROUND

This section illustrates useful background information without admission of any technique described herein representative of the state of the art.

Microelectromechanical systems, MEMS, resonators are being developed to provide the same functionality as quartz resonators with benefits such as smaller chip size, reduced cost, and increased robustness against shock and vibrations.

A key performance parameter in MEMS resonators is the equivalent series resistance, ESR. ESR is inversely proportional to a quality factor Q of the resonator. A further key parameter is the drive level dependency, DLD, meaning the dependence of the resonator frequency on driving power. The minimization of both the ESR and DLD are often desirable.

### SUMMARY

It is an object of certain embodiments of the present disclosure to reduce DLD of MEMS resonators or at least to provide an alternative to existing technology.

According to a first example aspect of the present disclosure there is provided a MEMS, microelectromechanical systems, resonator comprising:
a slanted resonator element, the slanted resonator element comprising a slanted resonating beam comprising single-crystalline silicon, wherein
the slanted resonating beam is configured to resonate in its length direction, and wherein a longitudinal axis of the slanted resonating beam is slanted (tilted) from a <100>direction of silicon.

In certain embodiments, the slanted resonating beam in itself is slanted in geometry and further a longitudinal axis of the slanted resonating beam is tilted from a <100>direction of silicon. In the event of a plurality of slanted resonator beams, the slanted resonating beams in themselves are slanted in geometry and further a longitudinal axis of the slanted resonating beams is tilted from a <100>direction of silicon.

The first aspect comprises both a single beam MEMS resonator, comprising a slanted resonator beam (or only one slanted resonator beam), and a MEMS resonator comprising a plurality of slanted resonator beams (the slanted resonator element comprises a plurality of slanted resonating beams).

Accordingly, in accordance with certain implementations there is provided a MEMS, microelectromechanical systems, resonator comprising:
a slanted resonator element, the slanted resonator element comprising a slanted resonating beam comprising single-crystalline silicon, wherein
the slanted resonating beam is configured to resonate in its length direction, and wherein a longitudinal axis of the slanted resonating beam is tilted from a <100>direction of silicon, wherein the slanted resonator element comprises only one slanted resonating beam.

And, in accordance with certain implementations there is provided a MEMS, microelectromechanical systems, resonator comprising:
a slanted resonator element, the slanted resonator element comprising a plurality of slanted resonating beams each slanted resonating beam comprising single-crystalline silicon, wherein
each slanted resonating beam is configured to resonate in its length direction, and wherein a longitudinal axis of each slanted resonating beam is tilted from a <100>direction of silicon.

In certain embodiments, said slanting is to reduce the effect of drive level dependency.

The <100>direction herein refers to the set of equivalent directions in Miller indices, e.g., the directions [100], [010], and [001]. In the following description, the notation (100) refers to a plane whose normal direction is [100], whereas the notation {100} refers to all planes equivalent to the plane (100) by symmetry.

In certain embodiments, the slanted resonating beam is in the form of a resonating beam skewed in one (and only one) direction.

In certain embodiments, the longitudinal axis is slanted (tilted) 16 to 22 degrees, more preferably 18 to 20 degrees, most preferably 19 degrees from said <100>direction.

In certain embodiments, the slanted resonating beam is in the form of a skewed rectangle.

In certain embodiments, the MEMS resonator comprises the slanted resonating beam in a general shape of a parallelogram.

In certain embodiments, the shorter two edges of the parallelogram are aligned parallel to a crystal orientation <100>and the two longer edges of the parallelogram are aligned at an angle 90°−α to the shorter two edges, wherein α is a slanting angle between the longitudinal axis of the slanted resonating beam and said <100>direction.

In certain embodiments, α is within the range extending from 16 to 22 degrees, more preferably 18 to 20 degrees, most preferably 19 degrees from said <100>direction.

In certain embodiments, the slanted resonating beam has the form of a parallelogram with adjacent sides of unequal lengths and angles non-right angled (i.e., rhomboid). In certain embodiments, the slanted resonating beam has an aspect ratio of greater than one. In certain embodiments, both ends (shorter edges) of the slanted resonating beam are aligned with a direction perpendicular to said <100>direction (which perpendicular direction may be another <100>direction in the event of single-crystalline silicon).

In certain embodiments, the slanted resonating beam is in the form of a skewed rectangle skewed along an axis which is both in the plane of the resonator element and perpendicular to the first-mentioned <100>direction (“first <100>direction”).

In certain embodiments, the skewed rectangle is unskewed in the first <100>direction. In certain embodiments, the skewed rectangle is skewed (slanted) 16 to 22 degrees, more preferably 18 to 20 degrees, most preferably 19 degrees from the first <100>direction (about one of the corners of the rectangle).

In certain embodiments, the resonator element is anchored at nodal points of the resonator element.

In certain embodiments, the resonator element comprises suspenders at nodal points of the resonator element to anchor the resonator element to a surrounding structure. In certain embodiments, a suspender is positioned at a center of a longer edge of the slanted resonating beam. In certain embodiments, the suspenders are aligned with a direction perpendicular to the longitudinal axis of the slanted resonating beam. In certain embodiments, the suspenders are slanted from the first <100>direction of silicon similarly as the resonating beams.

In certain embodiments, the MEMS resonator comprises a plurality of slanted resonating beams adjacent to each other, separated by respective trenches, and connected by respective connection elements, said plurality of slanted resonating beams connected by said connection elements thereby forming a stacked beam resonator.

In certain embodiments, said plurality of slanted resonating beams adjacent to each other are identical in their form. In certain embodiments, the shorter edges of the plurality of slanted resonating beams adjacent to each other are, respectively, aligned with each other.

In certain embodiments, each slanted resonating beam is tilted from the <100>direction of silicon in the same direction.

In certain embodiments, the slanted resonating element as such, or the resonating beam(s), is (are) slanted without rotating the resonating element (or resonator) as a whole.

In certain embodiments, said plurality of slanted resonating beams adjacent to each other are configured to resonate in a collective resonance mode, preferably in a length-extensional resonance mode.

In certain embodiments, said plurality of slanted resonating beams adjacent to each other have a common resonance mode shape.

In certain embodiments, more than 50% of the mass of the slanted resonator element consists of single-crystalline silicon.

In certain embodiments, the resonator is made of a (100) or {100} silicon wafer or a layer of single crystalline silicon that has its surface normal in alignment with a <100>crystalline direction of silicon.

In certain embodiments, the MEMS resonator comprises a material stack with a top electrode layer, a piezoelectric layer beneath the top electrode layer and a bottom electrode layer of single-crystalline silicon beneath the piezoelectric layer. In certain embodiments, the material stack is uniform throughout the slanted resonator (resonating) element.

In certain embodiments, the MEMS resonator comprises a layer of single-crystalline silicon doped to an average impurity concentration of at least 2*10¹⁹ cm⁻³, more preferably at least 1*10²⁰ cm⁻³.

According to a second example aspect there is provided a MEMS, microelectromechanical systems, resonator comprising a resonating element in shape of a parallelogram where the shorter two edges are aligned parallel to a crystal orientation <100>and the two longer edges of the resonator are aligned at an angle 90°−60 to the shorter two edges.

In certain embodiments, α is within the range extending from 16 to 22 degrees, more preferably 18 to 20 degrees, most preferably 19 degrees from said <100>direction.

In certain embodiments, the resonator is made of single crystalline silicon.

In certain embodiments, the resonating element (or beam) has a top surface having its normal in alignment with a <100>crystalline direction of silicon.

In certain embodiments, the resonator is made of a (100) silicon wafer or a layer of single crystalline silicon that has its surface normal to <100>orientation.

In certain embodiments, the resonator is configured to be excited by piezoelectric actuation.

Different non-binding example aspects and embodiments have been presented in the foregoing. The above embodiments and embodiments described later in this description are used to explain selected aspects or steps that may be utilized in implementations of the present invention. It should be appreciated that corresponding embodiments apply to other example aspects as well. Any appropriate combinations of the embodiments can be formed.

### BRIEF DESCRIPTION OF THE DRAWINGS

The invention will now be described, by way of example only, with reference to the accompanying drawings, in which:

FIG. 1 shows a prior art stacked beam MEMS resonator;

FIG. 2 shows a schematic top view of a MEMS resonator in accordance with certain embodiments of the present disclosure;

FIGS. 3a-3b show deformations in the MEMS resonator of FIG. 2 during resonance in accordance with certain embodiments;

FIG. 4 shows a schematic top view of a MEMS resonator in accordance with certain further embodiments;

FIG. 5 shows a more detailed presentation of a top view of a resonating beam in accordance with certain embodiments;

FIG. 6 shows schematically an example of a MEMS resonator material stack in accordance with certain embodiments;

FIG. 7 schematically shows an example of observed drive level dependency; and

FIG. 8 shows simulated resonance mode shape of a rotated MEMS resonator.

### DETAILED DESCRIPTION

In the following description, like numbers denote like elements.

FIG. 1 shows a top view of a prior art silicon MEMS resonator. The resonator comprises a plurality of resonating beams positioned in parallel and connected by connection elements. The resonating beams are in alignment with a <100>crystal axis of silicon.

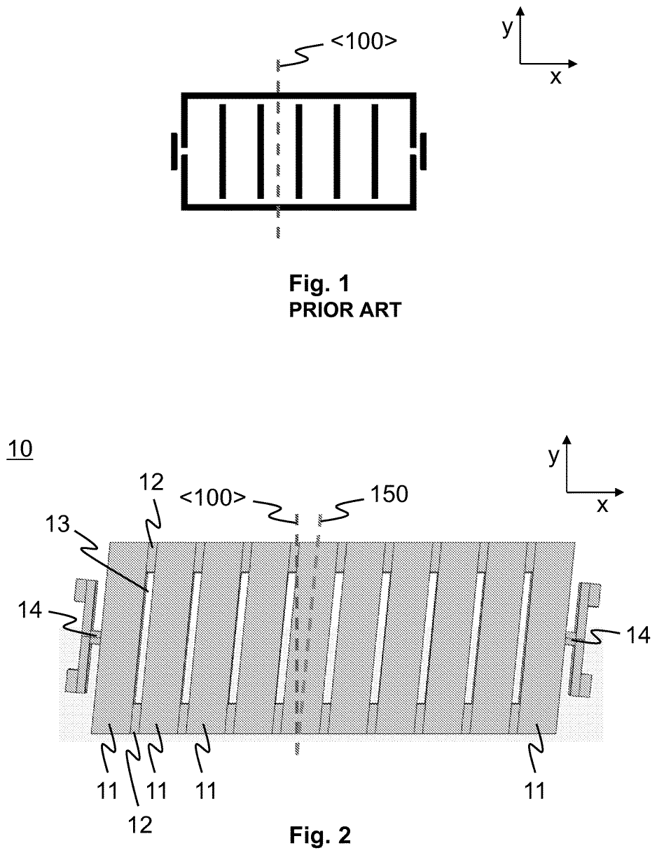

FIG. 2 shows a schematic top view of a MEMS resonator 10 in accordance with certain embodiments of the present disclosure. The MEMS resonator 10 comprises a slanted resonator (resonating) element. The resonator element comprises one or more slanted resonating beams 11. In the example shown in FIG. 2, the number of resonating beams is 10 although in other embodiments the number of resonating beams 11 can be different.

The resonating beams 11 comprise single-crystalline silicon. Adjacent resonating beams 11 are separated from each other by respective trenches 13. In certain embodiments, the trenches 13 extend to a cavity (not shown) beneath the resonating element. In certain embodiments, the cavity separates the resonating element from a substrate wafer, such as a SOI (silicon on insulator) wafer. Adjacent resonating beams are connected (coupled) with each other at their end portions by connection elements 12. A stacked beam resonator is thus formed.

Each resonating beam 11 is configured to resonate in its length direction. A longitudinal axis 150 of each resonating beam 11 is slanted (tilted) from a <100>direction of silicon (each resonating beam 11 is slanted in a skewed manner). Said slanting is to reduce the effect of drive level dependency, DLD.

In certain embodiments, the longitudinal axis of the resonating beams 11 is slanted 16 to 22 degrees, more preferably 18 to 20 degrees, most preferably 19 degrees from said <100>direction for optimal DLD cancellation in certain embodiments.

In certain embodiments, as shown in FIG. 2, each resonating beam 11 is in the form of a resonating beam skewed in one (and only one) direction (here: x-direction). Each resonating beam 11 is in the form of a skewed rectangle so that each resonating beam has the form of a parallelogram with adjacent sides of unequal lengths and angles non-right angled (i.e., rhomboid). The resonating beams 11 have an aspect ratio of greater than one. Both ends (shorter edges) of the resonating beams 11 are aligned with a direction perpendicular to said <100>direction. This perpendicular direction may be another <100>direction (“second <100>direction”) in the event of single-crystalline silicon. The skewed rectangles are skewed along an axis which is both in the plane of the resonator element (preferably a {100} plane) and perpendicular to the first mentioned <100>direction (“first <100>direction”). The skewed rectangles are unskewed in said first <100>direction. In certain embodiments, the skewed rectangles are skewed (slanted) 16 to 22 degrees, more preferably 18 to 20 degrees, most preferably 19 degrees from the first <100>direction (about one of the corners of the rectangle).

The resonator element is anchored at nodal points of the resonator element. In certain embodiments, as shown in FIG. 2, the resonator element comprises suspenders 14 at nodal points of the resonator element to anchor the resonator element to a surrounding structure. In certain embodiments, a respective suspender 14 is positioned at a center of an outer longer edge of both outermost resonating beams 11. In certain embodiments, the suspenders 14 are aligned with a direction perpendicular to the longitudinal axis of the resonating beams 11. In certain embodiments, the suspenders 14 are slanted from the first <100>direction of silicon similarly as the resonating beams 11.

In certain embodiments, as shown in FIG. 2, the resonating beams 11 adjacent to each other are identical in their form. The shorter edges of the resonating beams 11 are aligned with each other. The resonating beams 11 are configured to resonate in a collective resonance mode, preferably in a length-extensional, LE, resonance mode.

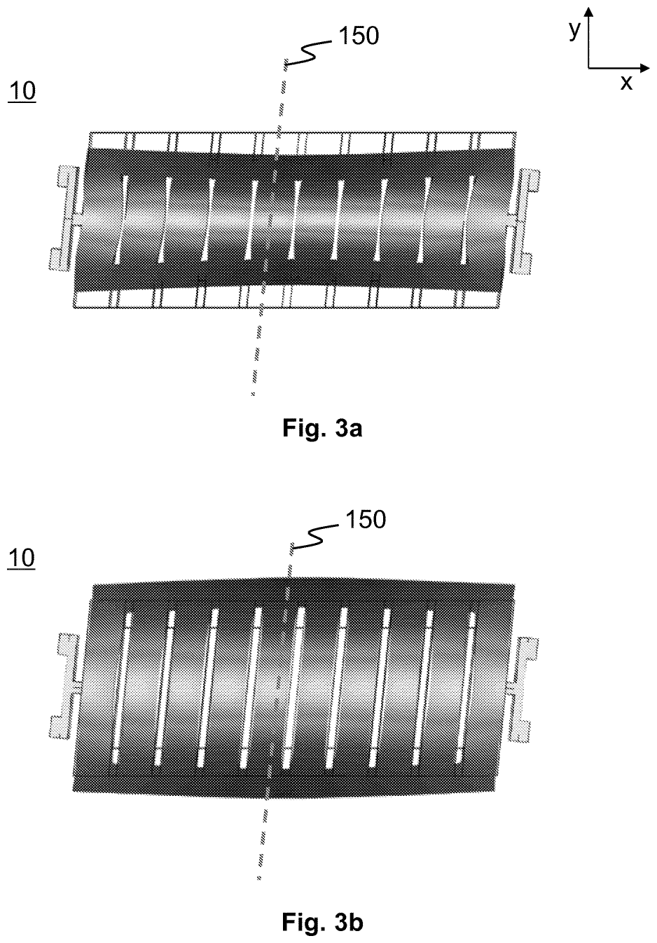

FIGS. 3a and 3b show deformations in the MEMS resonator 10 during resonance in accordance with certain embodiments. FIG. 3a shows one extremity of vibration in which the resonating beams are in their shortest configuration (contracted form), and FIG. 3b the other extremity in which the resonating beams are in their longest configuration (extended form). The darkness of the color in the FIGS. 3a and 3b indicate experienced displacement from a rest position. As will be noted, all resonating beams 11 substantially have a common resonance mode shape.

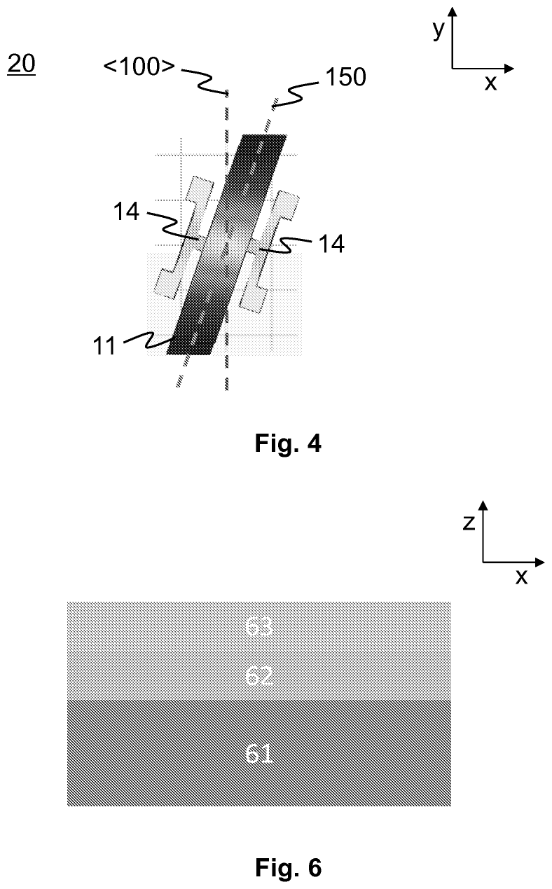

FIG. 4 shows a schematic top view of a MEMS resonator 20 in accordance with certain further embodiments. In these embodiments, the resonating element comprises only one resonating beam 11. Otherwise the embodiments shown in FIG. 4 correspond to the structure and operation of the preceding embodiments. Accordingly, the resonating beam 11 is configured to resonate in its length direction. The longitudinal axis 150 of the resonating beam 11 is slanted (tilted) from a <100>direction of silicon similarly as described in the preceding (the resonating beam 11 is slanted in a skewed manner).

The skewed resonating beam 11 (skewed rectangle) is skewed 16 to 22 degrees, more preferably 18 to 20 degrees, most preferably 19 degrees from the <100>direction (about one of the corners of the rectangle).

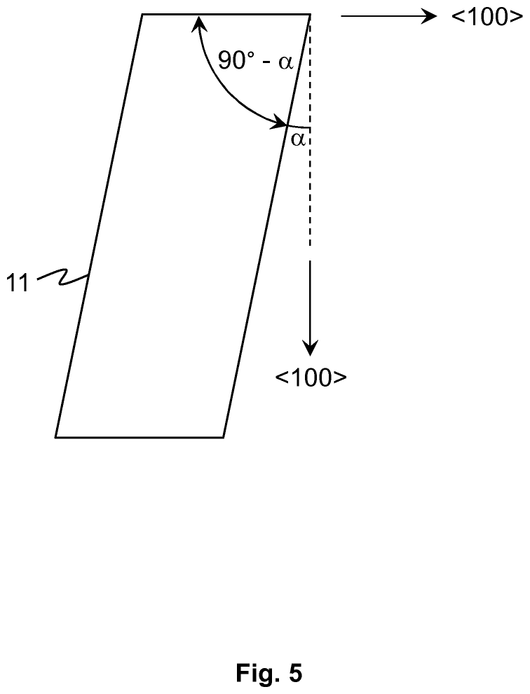

FIG. 5 shows a more detailed presentation of a top view of a resonating beam 11 in accordance with certain embodiments. The resonating beam 11 may be a resonating beam forming part of the MEMS resonator 10 or 20 shown in the preceding. The resonator beam 11 is in the general shape of a parallelogram where the two longer edges are aligned at an angle α (with respect) to a first <100>crystal orientation (e.g. the [100] direction), and the two shorter edges are aligned parallel to a second <100>crystal orientation (e.g. the [010] direction). Accordingly, the two longer edges of the resonating beam 11 are aligned at an angle 90°−α (with respect) to the shorter two edges. The two <100>directions lie within a {100} plane of the substrate wafer concerned (wafer plane). A third <100>crystal orientation (e.g. the [001] direction) is normal to the wafer plane. Accordingly, a resonating beam 11 being in a plane of a silicon substrate wafer and having two <100>crystalline directions lying in the plane and one <100>crystalline direction perpendicular to the plane with the longitudinal direction of the resonating beam 11 slanted from one <100>direction in the plane is disclosed.

FIG. 6 shows schematically a MEMS resonator material stack in accordance with certain embodiments. The material stack is applicable to the shown resonators 10, 20.

The material stack comprises a top electrode layer 63, a piezoelectric layer 62 beneath the top electrode layer 63 for piezoelectric actuation of the resonating element into a resonance mode, and a bottom electrode layer 61 of single-crystalline silicon beneath the piezoelectric layer 62. In certain embodiments, the material stack is uniform throughout the resonator element. It should be noted that the material stack shown in FIG. 6 merely presents one example of an applicable material stack. Different material stacks may be realized in other implementations. In certain embodiments, the top electrode layer 63 is a metallic layer, such as a layer of gold. In certain embodiments, the piezoelectric layer 62 is of AlN. Accordingly, in certain embodiments, the material stack is a Si/AlN/Au material stack. In certain embodiments, the material stack comprises a SiO₂ layer. This is to improve thermal frequency stability of the MEMS resonator in certain embodiments, such as to compensate for a changed or more negative temperature coefficient of frequency TCF (such as TCF1) caused by the slanting. In certain embodiments, the SiO₂ layer resides below (or directly beneath) the single-crystalline silicon layer 61. In certain embodiments, the SiO₂ layer resides above the single-crystalline silicon layer 61 (such as in between the single-crystalline silicon layer 61 and the piezoelectric layer 62). In certain embodiments, the SiO₂ layer resides above the piezoelectric layer 62 (such as in between the piezoelectric layer 62 and the top electrode layer 63). In certain embodiments, the SiO₂ layer resides above the top electrode layer 63. In such embodiments, the SiO₂ layer may be implemented covering (e.g., by patterning) only a part of the top electrode layer 63, such as a center region, to allow required trimming of the top electrode layer 63, such as trimming of gold.

In certain embodiments, more than 50% of the mass of the resonator element consists of single-crystalline silicon. In certain embodiments, the layer of single-crystalline silicon (layer 61) is doped to an average impurity concentration of at least 2*10¹⁹ cm⁻³, more preferably at least 1*10²⁰ cm⁻³.

Without limiting the scope and interpretation of the patent claims, certain technical effects of one or more of the example embodiments disclosed herein are listed in the following. A technical effect is reduction of drive level dependency, DLD, of a silicon MEMS resonator. A further technical effect is reduction of ESR and increase in the quality factor Q.

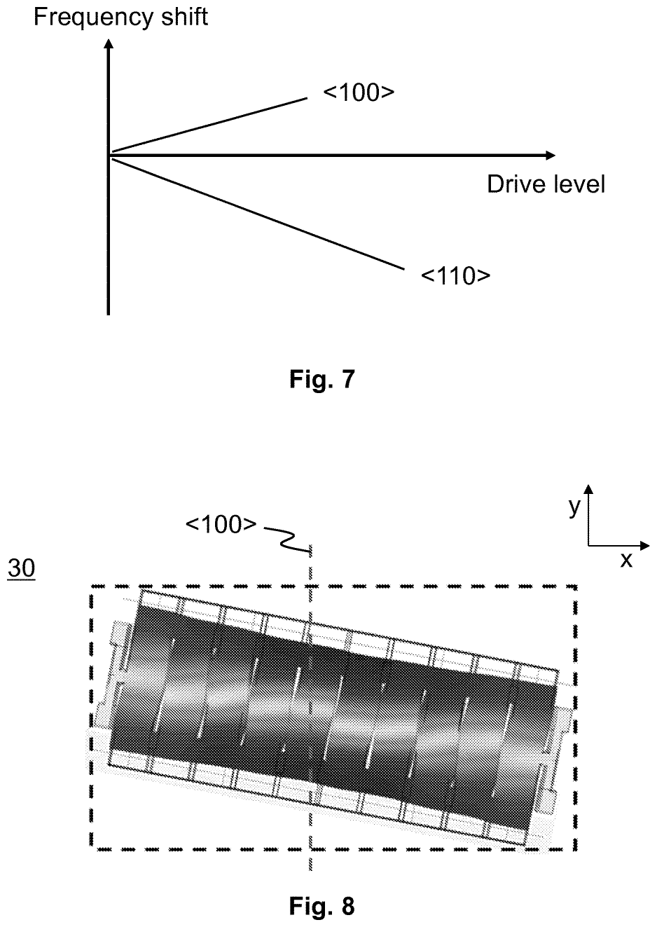

The technical effects are further elaborated with the aid of FIGS. 7 and 8. FIG. 7 schematically shows an example of observed drive level dependency, DLD, for resonating beams with certain alignments. It is observed that DLD is positive for <100>aligned resonating beams and negative e.g. for <110>aligned resonator beams. Accordingly, the effect of DLD reduction can be achieved by slanting the resonator beam from the <100>direction. FIG. 8 shows a simulated resonance mode shape of a stacked beam MEMS resonator 30 rotated as a whole. It is observed that the resonance mode shape of the resonator 30 is fairly poor compared to that of the resonator 10 shown in FIGS. 3a and 3b. Consequently, a better Q value and, thus, a reduced ESR value can be obtained by slanting. Furthermore, the rotated resonator 30 will require a larger orthogonal footprint on a die compared to the slanted MEMS resonator.

The foregoing description has provided by way of non-limiting examples of particular implementations and embodiments of the invention a full and informative description of the best mode presently contemplated by the inventors for carrying out the invention. It is however clear to a person skilled in the art that the invention is not restricted to details of the embodiments presented above, but that it can be implemented in other embodiments using equivalent means without deviating from the characteristics of the invention.

Furthermore, some of the features of the above-disclosed embodiments of this invention may be used to advantage without the corresponding use of other features. As such, the foregoing description should be considered as merely illustrative of the principles of the present invention, and not in limitation thereof. Hence, the scope of the invention is only restricted by the appended patent claims.

1-18. (canceled)

19. A MEMS, microelectromechanical systems, resonator comprising:
only one slanted resonator element, the slanted resonator element comprising a slanted resonating beam comprising single-crystalline silicon, wherein
the slanted resonating beam is configured to resonate in its length direction, and wherein a longitudinal axis of the slanted resonating beam is tilted from a <100>direction of silicon, wherein the slanted resonator element comprises only one slanted resonating beam.

20. The MEMS resonator of claim 1, wherein the slanted resonating beam is in the form of a skewed rectangle.

21. The MEMS resonator of claim 1, wherein the slanted resonating beam is in the form of a skewed rectangle skewed along an axis which is both in the plane of the slanted resonator element and perpendicular to said <100>direction.

22. The MEMS resonator of claim 1, wherein the slanted resonator element is anchored at nodal points of the slanted resonator element.

23. The MEMS resonator of claim 1, wherein more than 50% of the mass of the slanted resonator element consists of single-crystalline silicon.

24. The MEMS resonator of claim 1, comprising a material stack with a top electrode layer, a piezoelectric layer beneath the top electrode layer and a bottom electrode layer of single-crystalline silicon beneath the piezoelectric layer.

25. A MEMS, microelectromechanical systems, resonator comprising: a plurality of slanted resonator elements, each slanted resonator element comprising a slanted resonating beam comprising single-crystalline silicon, wherein the slanted resonating beam is configured to resonate in its length direction, and wherein a longitudinal axis of the slanted resonating beam is tilted from a <100>direction of silicon, the plurality of slanted resonating beams being adjacent to each other, separated by respective trenches, and connected by respective connection elements, said plurality of slanted resonating beams connected by said connection elements thereby forming a stacked beam resonator, wherein the shorter edges of the plurality of slanted resonating beams adjacent to each other are, respectively, aligned with each other.

26. The MEMS resonator of claim 26, wherein said plurality of slanted resonating beams adjacent to each other are configured to resonate in a collective resonance mode, preferably in a length-extensional resonance mode.

27. The MEMS resonator of claim 26, wherein said plurality of slanted resonating beams adjacent to each other have a common resonance mode shape.

28. The MEMS resonator of claim 26, wherein at least one slanted resonating beam of the plurality of slanted resonator elements is in the form of a skewed rectangle.

29. The MEMS resonator of claim 26, wherein at least one slanted resonating beam of the plurality of slanted resonator elements is in the form of a skewed rectangle skewed along an axis which is both in the plane of the slanted resonator element having at least one slanted resonating beam and perpendicular to said <100>direction.

30. The MEMS resonator of claim 26, wherein each slanted resonating beam is tilted from the <100>direction of silicon in the same direction.

31. The MEMS resonator of claim 26, wherein the slanted resonating beams adjacent to each other are identical in their form.

32. The MEMS resonator of claim 26, wherein the longitudinal axis is tilted 16 to 22 degrees, more preferably 18 to 20 degrees, most preferably 19 degrees from the <100>direction.

33. The MEMS resonator of claim 26, wherein the slanted resonator element(s) is/are anchored at nodal points of the slanted resonator element.

34. The MEMS resonator of claim 26, wherein more than 50% of the mass of the slanted resonator element(s) consists of single-crystalline silicon.

35. The MEMS resonator of claim 26, comprising a material stack with a top electrode layer, a piezoelectric layer beneath the top electrode layer and a bottom electrode layer of single-crystalline silicon beneath the piezoelectric layer.

36. The MEMS resonator of claim 26, comprising a layer of single-crystalline silicon doped to an average impurity concentration of at least 2*10¹⁹ cm⁻³, more preferably at least 1*10²⁰ cm⁻³.

37. The MEMS resonator of claim 26, comprising slanted resonating beams in a general shape of a parallelogram.

38. The MEMS resonator of claim 38, where the shorter two edges of the parallelogram are aligned parallel to a crystal orientation <100>and the two longer edges of the parallelogram are aligned at an angle 90°−α to the shorter two edges, wherein α is a slanting angle between the longitudinal axis of the slanted resonating beam and said crystal orientation <100>.
